(19) United States
(12) Patent Application Publication
(10) Pub. No.: US 2016/0118154 A1
(43) Pub. Date: Apr. 28, 2016

(54) SILICON/CARBON COMPOSITE, SILICON ALLOY/CARBON COMPOSITE, AND METHODS FOR PRODUCING THE SAME

(71) Applicant: L'Air Liquide, Societe Anonyme pour l'Etude et l'Exploitation des Procedes Georges Claude, Paris (FR)

(72) Inventors: Aurelie DUMONT, Ibaraki (JP); Patrick GINET, Ibaraki (JP); Shingo OKUBO, Ibaraki (JP)

(73) Assignee: L'Air Liquide, Societe Anonyme pour l'Etude et l'Exploitation des Procedes Georges Claude, Paris (FR)

(21) Appl. No.: 14/924,049

(22) Filed: Oct. 27, 2015

(30) Foreign Application Priority Data
Oct. 28, 2014 (JP) 2014-219080
Aug. 5, 2015 (JP) 2015-154960

(51) Int. Cl. H01B 1/04; C23C 16/24; C23C 16/26

(52) U.S. Cl. CPC H01B 1/04; C23C 16/26; C23C 16/24

(57) ABSTRACT

A silicon/carbon composite or a silicon alloy/carbon composite is formed with a homogeneous silicon-containing thin film or silicon-containing alloy thin film on the surface of a conductive carbon material, where the composite may be used for a large-capacity electrical storage device when used as a negative electrode material for forming an electrical storage device negative electrode, and exhibits excellent charge-discharge cycle characteristics. A carbon-containing thin film is formed on a surface of a conductive carbon material by chemical vapor deposition (CVD) that utilizes a carbon-containing gas and a silicon-containing thin film or a silicon-containing alloy thin film is formed on the conductive carbon material by chemical vapor deposition (CVD) that utilizes a silicon-containing gas alone, or utilizes a silicon-containing gas and a carbon-containing gas.

### CROSS-REFERENCE TO RELATED APPLICATIONS

This application claims the benefit of priority under 35 U.S.C. §119 (a) and (b) to Japanese patent application No. 2014-219080, filed Oct. 28, 2014 and Japanese patent application 2015-154960, filed Aug. 5, 2015, the entire contents of which are incorporated herein by reference.

### BACKGROUND

1. Field of the Invention

The present invention relates to a silicon/carbon composite (silicon-carbon composite), a silicon alloy/carbon composite (silicon alloy-carbon composite), and methods for producing the same. More specifically, the invention relates to a silicon/carbon composite in which a homogeneous silicon-containing thin film is formed on the surface of a conductive carbon material, a silicon alloy/carbon composite in which a homogeneous silicon-containing alloy thin film is formed on the surface of a conductive carbon material, and methods for producing the same.

2. Related Art

In recent years, a high-voltage electrical storage device having high energy density has been desired as a power supply for driving an electronic device. A lithium-ion battery, a lithium-ion capacitor, and the like have been anticipated as such an electrical storage device.

Use of a material having a high lithium occlusion capacity has been studied in order to implement an increase in output and energy density required for the electrical storage device. It has been known that a large-capacity electrical storage device is obtained by utilizing nanometer-sized silicon or a nanometer-sized silicon alloy as a negative electrode material (active material), for example.

An electrical storage device negative electrode production process employed at present utilizes materials (e.g., binder and conductive additive) that do not directly contribute to an increase in capacity, in addition to the negative electrode material. The capacity of the electrical storage device is expected to be increased by reducing the amount of these materials. On the other hand, studies have been conducted that aim at increasing the capacity of the electrical storage device by utilizing a composite of a conductive carbon material and silicon. For example, a composite of a carbon material such as graphite or carbon nanofibers (CNF) and silicon has been proposed as a silicon/carbon composite that may be applied to a lithium-ion battery.

Chemical vapor deposition (CVD) that utilizes a silane or a volatile silicon-based precursor has been known as a method for coating a carbon material with silicon. However, it is impossible to coat commercially available CNF with silicon at a uniform thickness (see Non-Patent Literatures 1 and 2, for example). Non-Patent Literatures 3 and 4 propose a method that mixes polyvinylidene fluoride (PVDF) (organic binder) with CNF, heats the mixture, and performs silicon CVD to obtain a uniformly-coated silicon/CNF composite.

When producing a composite material that includes a carbon material and another inorganic/organic material, the physicochemical characteristics of the composite material are significantly affected by the affinity between the materials. Affinity between CNF and a polymer or a plastic has been studied in order to provide a novel functional composite material for which physicochemical characteristics (e.g., electrical/thermal conductivity and frictional characteristics) are controlled. Attempts have also been made to improve the mechanical characteristics of CNF through pretreatment. For example, Patent Literatures 1 and 2 disclose a method that oxidizes CNF produced by electrospinning. Patent Literatures 3 and 4 disclose a method that treats CNF with carbon dioxide heated to 1100° C. or less. Patent Literature 5 discloses a method that treats CNF with an acid solution.

Patent Literature 6 discloses that a silicon layer can be uniformly deposited when amorphous carbon has been deposited. Patent Literatures 7 and 8 disclose that a carbon layer protects a silicon layer when a silicon/carbon multilayered structure is produced.

Patent Literature 9 discloses that affinity to a polymer is improved, and the physicochemical characteristics (e.g., electrical/thermal conductivity and frictional characteristics) of a composite are improved by treating CNF using plasma CVD that utilizes acetylene as a carbon source.

### CITATION LIST

### Patent Literature

[PTL 1] CN-A-102074683
[PTL 2] KR-A-2005-0014033
[PTL 3] KR-A-2003-0095694
[PTL 4] Korean Patent No. 100744832
[PTL 5] Korean Patent No. 101315486
[PTL 6] WO2013/060790
[PTL 7] US-A1-2012/0264020
[PTL 8] US-A1-2014/0021415
[PTL 9] JP-A-2006-213569

### Non-Patent Literature

[NPL 1] Gerard K. Simon, Benji Maruyama, Michael F. Durstock, David J. Burton, Tarun Goswami, Journal of Power Sources, 196, 10254-10257, 2011
[NPL 2] Jane Y. Howe, David J. Burton, Yue Qi, Harry M. Meyer III, Maryam Nazri, G. Abbas Nazri, Andrew C. Palmer, Patrick D. Lake, Journal of Power Sources, 221, 455-461, 2013
[NPL 3] C. K. Chan, H. Peng, G. Liu, K. Mcllwrath, X. F. Zhang, R. A. Huggins, Y. Cui, Nature Nanotechnol., 3, 31, 2008
[NPL 4] L.-F.-Cui, Y. Yang, C.-M. Hsu, Y. Cui, Nano Lett., 9, 3370, 2009

As described above, most of the CNF surface treatment methods have been proposed for producing a composite material of CNF and a resin, and aim at improving the mechanical characteristics of the resulting composite material. A technique that relates to electrical storage device applications, and utilizes only a vapor-phase treatment has not been proposed.

When silicon or a silicon alloy is directly deposited on commercially available CNF, particulate silicon or a particulate silicon alloy tends to adhere to the surface of the CNF, and a homogeneous film may not be obtained. When particulate silicon or a particulate silicon alloy adheres to CNF, the electrical contact between CNF and silicon or the silicon alloy is easily lost, and the amount of silicon or silicon alloy that can be used for lithium occlusion decreases. This makes it difficult to implement a large-capacity electrical storage device.

The volume of silicon or a silicon alloy increases or decreases to a large extent upon insertion or extraction of lithium ions. When a material in which a homogenous (uniform) silicon-containing thin film or silicon-containing alloy thin film is not formed on the surface of CNF is used as a negative electrode material, the resulting negative electrode deteriorates (e.g., due to removal of silicon or the silicon alloy) when charge and discharge are repeated, and excellent charge-discharge cycle characteristics cannot be obtained.

### SUMMARY OF THE INVENTION

An object of several aspects of the invention is to solve at least some of the above problems, and provide a method for producing a silicon/carbon composite that can form a homogeneous silicon-containing thin film on the surface of a conductive carbon material, and a method for producing a silicon alloy/carbon composite that can form a homogeneous silicon-containing alloy thin film on the surface of a conductive carbon material.

An object of several aspects of the invention is to provide a silicon/carbon composite and a silicon alloy/carbon composite that can provide a large-capacity electrical storage device when used as a negative electrode material for forming an electrical storage device negative electrode, and exhibit excellent charge-discharge cycle characteristics.

The invention was conceived in order to solve at least some of the above problems, and may be implemented as follows (see the following aspects and application examples).

### APPLICATION EXAMPLE 1

According to one aspect of the invention, a method for producing a silicon/carbon composite includes:

a step (a) that forms a carbon-containing thin film on a surface of a conductive carbon material by chemical vapor deposition (hereinafter may be abbreviated as “CVD”) that utilizes a carbon-containing gas; and

a step (b) that forms a silicon-containing thin film on the conductive carbon material by chemical vapor deposition (CVD) that utilizes a silicon-containing gas.

### APPLICATION EXAMPLE 2

In the method for producing a silicon/carbon composite according to Application Example 1, the conductive carbon material may be carbon nanofibers or a graphite powder.

### APPLICATION EXAMPLE 3

In the method for producing a silicon/carbon composite according to Application Example 1 or 2, the carbon-containing gas may be at least one gas selected from the group consisting of a saturated hydrocarbon having 1 to 10 carbon atoms that is unsubstituted or substituted with a substituent, an unsaturated hydrocarbon having 2 to 10 carbon atoms that is unsubstituted or substituted with a substituent, an alicyclic hydrocarbon having 3 to 10 carbon atoms that is unsubstituted or substituted with a substituent, and an aromatic hydrocarbon having 6 to 30 carbon atoms that is unsubstituted or substituted with a substituent.

### APPLICATION EXAMPLE 4

In the method for producing a silicon/carbon composite according to Application Example 3, the substituent may be at least one substituent selected from the group consisting of an acetyl group, a hydroxyl group, a carboxyl group, an aldehyde group, a carbonyl group, a cyano group, an amino group, B, P, S, F, and Cl.

### APPLICATION EXAMPLE 5

In the method for producing a silicon/carbon composite according to any one of Application Examples 1 to 4, the silicon-containing gas may be a gas represented by the following general formula (1),

SiₙH₂ₙ₊₂ (1)

wherein n is an integer from 1 to 6.

### APPLICATION EXAMPLE 6

According to another aspect of the invention, a method for producing a silicon alloy/carbon composite includes:

a step (a) that forms a carbon-containing thin film on a surface of a conductive carbon material by chemical vapor deposition (CVD) that utilizes a carbon-containing gas; and

a step (b) that forms a silicon-containing alloy thin film on the conductive carbon material by chemical vapor deposition (CVD) that utilizes a silicon-containing gas and a carbon-containing gas.

### APPLICATION EXAMPLE 7

According to another aspect of the invention, a method for producing a silicon alloy/carbon composite includes:

a step (b) that forms a silicon-containing alloy thin film on a surface of a conductive carbon material by chemical vapor deposition (CVD) that utilizes a silicon-containing gas and a carbon-containing gas.

### APPLICATION EXAMPLE 8

In the method for producing a silicon alloy/carbon composite according to Application Example 6 or 7, the conductive carbon material may be carbon nanofibers or a graphite powder.

### APPLICATION EXAMPLE 9

In the method for producing a silicon alloy/carbon composite according to any one of Application Examples 6 to 8, the carbon-containing gas may be at least one gas selected from the group consisting of a saturated hydrocarbon having 1 to 10 carbon atoms that is unsubstituted or substituted with a substituent, an unsaturated hydrocarbon having 2 to 10 carbon atoms that is unsubstituted or substituted with a substituent, an alicyclic hydrocarbon having 3 to 10 carbon atoms that is unsubstituted or substituted with a substituent, and an aromatic hydrocarbon having 6 to 30 carbon atoms that is unsubstituted or substituted with a substituent.

### APPLICATION EXAMPLE 10

In the method for producing a silicon alloy/carbon composite according to Application Example 9, the substituent may be at least one substituent selected from the group consisting of an acetyl group, a hydroxyl group, a carboxyl group, an aldehyde group, a carbonyl group, a cyano group, an amino group, B, P, S, F, and Cl.

### APPLICATION EXAMPLE 11

In the method for producing a silicon alloy/carbon composite according to any one of Application Examples 6 to 10, the silicon-containing gas may be a gas represented by the following general formula (1),

SiₙH₂ₙ₊₂ (1)

wherein n is an integer from 1 to 6.

### APPLICATION EXAMPLE 12

According to another aspect of the invention, a silicon/carbon composite includes:

a conductive carbon material, a carbon-containing thin film being formed on the surface of the conductive carbon material by chemical vapor deposition (CVD) that utilizes a carbon-containing gas; and

a silicon-containing thin film that is formed on the conductive carbon material by chemical vapor deposition (CVD) that utilizes a silicon-containing gas.

### APPLICATION EXAMPLE 13

In the silicon/carbon composite according to Application Example 12, the carbon-containing thin film formed on the surface of the conductive carbon material may have a thickness of 0.1 to 1000 nm.

### APPLICATION EXAMPLE 14

The silicon/carbon composite according to Application Example 12 or 13 may be used as a negative electrode material for forming an electrical storage device negative electrode.

### APPLICATION EXAMPLE 15

According to another aspect of the invention, a silicon alloy/carbon composite includes:

a conductive carbon material; and

a silicon-containing alloy thin film that is formed on the conductive carbon material by chemical vapor deposition (CVD) that utilizes a silicon-containing gas and a carbon-containing gas.

### APPLICATION EXAMPLE 16

In the silicon alloy/carbon composite according to Application Example 15, the carbon-containing thin film formed on the surface of the conductive carbon material by chemical vapor deposition (CVD) that utilizes the carbon-containing gas may have a thickness of 0.1 to 1000 nm.

### APPLICATION EXAMPLE 17

The silicon alloy/carbon composite according to Application Example 15 or 16 may be used as a negative electrode material for forming an electrical storage device negative electrode.

The methods for producing a silicon/carbon composite and a silicon alloy/carbon composite according to the aspects of the invention can form a homogeneous silicon-containing thin film or silicon-containing alloy thin film on the surface of a conductive carbon material. A large-capacity electrical storage device that exhibits excellent charge-discharge cycle characteristics can be obtained by utilizing the resulting silicon/carbon composite or silicon alloy/carbon composite as a negative electrode material for producing an electrical storage device.

### BRIEF DESCRIPTION OF DRAWINGS

FIG. 1 is a view schematically illustrating the configuration of a CVD thin film-forming device that can be used in connection with the embodiments of the invention.

FIG. 2 illustrates an SEM photograph of a carbon-containing thin film formed on a silicon substrate (provided with a thermal oxide film), and the XPS depth profile of the carbon-containing thin film.

FIG. 3 illustrates an SEM photograph of CNF on which a silicon-containing thin film is formed.

FIG. 4 is a graph illustrating the charge-discharge cycle characteristics of a half-cell produced using each negative electrode material (see FIG. 3).

FIG. 5 illustrates an SEM photograph of graphite on which a silicon-containing thin film is formed.

FIG. 6 is a graph illustrating the charge-discharge cycle characteristics of a half-cell produced using each negative electrode material (see FIG. 5).

FIG. 7 illustrates an SEM photograph of CNF on which a silicon-containing alloy thin film is formed.

FIG. 8 is a graph illustrating the charge-discharge cycle characteristics of a half-cell produced using each negative electrode material (see FIG. 7).

### DETAILED DESCRIPTION OF THE INVENTION

Exemplary embodiments of the invention are described in detail below. Note that the invention is not limited to the following exemplary embodiments. It should be understood that the invention includes various modifications that may be made of the following exemplary embodiments without departing from the scope of the invention.

### 1. METHODS FOR PRODUCING SILICON/CARBON COMPOSITE AND SILICON ALLOY/CARBON COMPOSITE

Methods for producing silicon/carbon composite and a silicon alloy/carbon composite according to the embodiments of the invention form a CVD thin film on the surface of a conductive carbon material using a CVD thin film-forming device. The configuration of the CVD thin film-forming device that can be used in connection with the embodiments of the invention, and the methods for producing a silicon/carbon composite and a silicon alloy/carbon composite according to the embodiments of the invention are sequentially described below.

Note that the term “silicon alloy” used herein refers to a material that includes silicon, and a metal element or a non-metal element other than silicon (or a mixture thereof) (preferably includes silicon and a non-metal element), and exhibits metallic properties.

### 1.1. CVD Thin Film-Forming Device

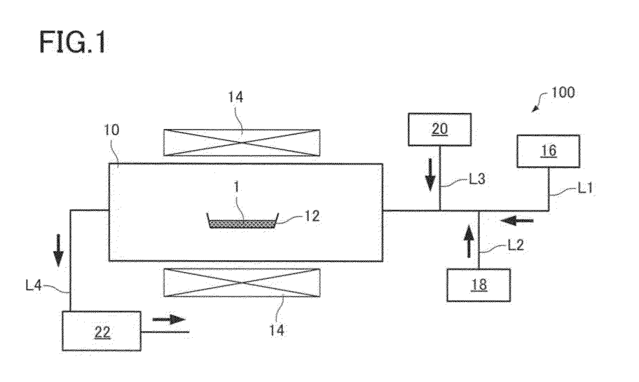

FIG. 1 is a view schematically illustrating the configuration of the CVD thin film-forming device that can be used in connection with one embodiment of the invention. As illustrated in FIG. 1, a CVD thin film-forming device 100 includes a reaction vessel 10 into which a boat 12 that holds a conductive carbon material 1 can be inserted, a furnace 14 (heating means) that is disposed around the reaction vessel 10, a carrier gas cylinder 16 that functions as a carrier gas (e.g., nitrogen gas) supply source, a carbon-containing gas cylinder 18 that functions as a carbon-containing gas supply source, a silicon-containing gas cylinder 20 that functions as a silicon-containing gas supply source, and a vacuum pump 22 that is provided on the downstream side of the reaction vessel 10. The reaction vessel 10 and the boat 12 are formed of quartz (SiO₂).

The carrier gas cylinder 16 is connected to the reaction vessel 10 through a line L1. A shut-off valve or a flow regulator (e.g., mass flow controller) (not illustrated in FIG. 1) may be provided to the line L1. The carbon-containing gas cylinder 18 is connected to the reaction vessel 10 through a line L2, and the silicon-containing gas cylinder 20 is connected to the reaction vessel 10 through a line L3. A shut-off valve or a flow regulator (not illustrated in FIG. 1) may be provided to the lines L2 and L3 in the same manner as the line L1.

The vacuum pump 22 is connected to the reaction vessel 10 through an exhaust line L4. The vacuum pump 22 is provided on the downstream side of the reaction vessel 10. The pressure inside the reaction vessel 10 can be adjusted while exhausting gas from the reaction vessel 10 through the exhaust line L4 by driving the vacuum pump 22.

### 1.2. Methods for Producing Silicon/Carbon Composite and Silicon Alloy/Carbon Composite

A method for producing a silicon/carbon composite according to one embodiment of the invention (hereinafter may be referred to as “first embodiment”) includes a step (a) that forms a carbon-containing thin film on the surface of a conductive carbon material by chemical vapor deposition (CVD) that utilizes a carbon-containing gas, and a step (b) that forms a silicon-containing thin film on the conductive carbon material by chemical vapor deposition (CVD) that utilizes a silicon-containing gas. A method for producing a silicon alloy/carbon composite according to one embodiment of the invention (hereinafter may be referred to as “second embodiment”) includes a step (a) that forms a carbon-containing thin film on the surface of a conductive carbon material by chemical vapor deposition (CVD) that utilizes a carbon-containing gas, and a step (b) that forms a silicon-containing alloy thin film on the conductive carbon material by chemical vapor deposition (CVD) that utilizes a silicon-containing gas and a carbon-containing gas. A method for producing a silicon alloy/carbon composite according to one embodiment of the invention (hereinafter may be referred to as “third embodiment”) includes a step (b) that forms a silicon-containing alloy thin film on a conductive carbon material by chemical vapor deposition (CVD) that utilizes a silicon-containing gas and a carbon-containing gas. The method for producing a silicon/carbon composite according to the first embodiment, the method for producing a silicon alloy/carbon composite according to the second embodiment, and the method for producing a silicon alloy/carbon composite according to the third embodiment may be implemented by using the above CVD thin film-forming device 100. Each step is described below with reference to FIG. 1.

### 1.2.1. Step (a)

The step (a) forms the carbon-containing thin film on the surface of the conductive carbon material by CVD that utilizes the carbon-containing gas. The step (a) is a pretreatment step for forming a homogeneous silicon-containing thin film or silicon-containing alloy thin film on the surface of the conductive carbon material. The inventors conducted studies, and found that a homogeneous silicon-containing thin film or silicon-containing alloy thin film can be formed by CVD on the surface of the conductive carbon material in the subsequent step (b) by forming a homogeneous carbon-containing thin film by CVD in advance on the surface of the conductive carbon material. Therefore, when producing a silicon alloy/carbon composite, the step (b) may be performed without performing the step (a) as long as the surface of the conductive carbon material (base) is homogeneous, as in the above third embodiment.

The step (a) may be performed as described below, for example.

The conductive carbon material 1 is placed on the boat 12, which is introduced into the reaction vessel 10. The term “conductive carbon material” used herein refers to a material that includes carbon, and has an electrical resistivity of 10⁷ ohms·cm or less. Examples of the conductive carbon material 1 include graphite, amorphous carbon, carbon fibers, carbon nanofibers (CNF), carbon nanotubes, coke, activated carbon, and the like. Among these, carbon nanofibers and a graphite powder are preferable from the viewpoint of capacity and volume density.

The carbon nanofibers may be solid carbon nanofibers that do not have a hollow part that extends in the longitudinal direction, or may be hollow carbon nanofibers that have a hollow part that extends in the longitudinal direction. It is preferable that the carbon nanofibers be a cylindrical laminate in which fifteen or more cylindrical graphene sheets are coaxially stacked in the diametrical direction, and more preferably the cylindrical laminate in which the cylindrical plane is the c-axis plane. When the carbon nanofibers have such a structure, the carbon nanofibers exhibit sufficient mechanical strength and elasticity.

The average length of the carbon nanofibers is preferably 0.1 to 10 micrometers. The average diameter of the carbon nanofibers is preferably 10 to 200 nm.

The carbon nanofibers may be produced using an arbitrary method. It is preferable to produce the carbon nanofibers using a vapor-phase growth method. The carbon nanofibers produced using a vapor-phase growth method have high purity, and show only a small variation in quality.

The graphite powder is not particularly limited. Examples of the graphite powder include natural graphite, synthetic graphite, and the like. The shape of the graphite powder is not particularly limited.

Nitrogen gas is introduced into the reaction vessel 10 from the carrier gas cylinder 16 through the line L1, and the pressure inside the reaction vessel 10 is maintained at a constant pressure of 0.01 to 760 Torr (preferably 0.1 to 600 Torr) while exhausting gas from the reaction vessel 10 through the exhaust line L4. The reaction vessel 10 is then heated to 600 to 1200° C. (preferably 700 to 1100° C.) using the furnace 14.

When the temperature and the pressure inside the reaction vessel 10 have become constant, the carbon-containing gas is supplied from the carbon-containing gas cylinder 18 through the line L2 to introduce a carbon-containing gas/nitrogen mixed gas into the reaction vessel 10. The carbon-containing gas and nitrogen are preferably mixed so that the concentration of the carbon-containing gas in the mixed gas is 0.1 to 5%, and more preferably 0.5 to 3.5%. The flow rate of the carbon-containing gas/nitrogen mixed gas is set to about 5 to 500 sccm, and preferably about 10 to 300 sccm. In the example illustrated in FIG. 1, the carbon-containing gas supplied from the carbon-containing gas cylinder 18 is mixed into the flow of the carrier gas. Note that the carrier gas may be bubbled into the carbon-containing gas cylinder 18, and the resulting carbon-containing gas may be introduced into the reaction vessel 10.

Examples of the carbon-containing gas include a hydrocarbon such as a saturated hydrocarbon having 1 to 10 carbon atoms, an unsaturated hydrocarbon having 2 to 10 carbon atoms, an alicyclic hydrocarbon having 3 to 10 carbon atoms, and an aromatic hydrocarbon having 6 to 30 carbon atoms. These hydrocarbons may be used either alone or in combination.

Examples of the saturated hydrocarbon having 1 to 10 carbon atoms include methane, ethane, propane, butane, pentane, hexane, heptane, octane, nonane, decane, and structural isomers thereof. Examples of the unsaturated hydrocarbon having 2 to 10 carbon atoms include an alkene such as ethene, propene, butene, pentene, hexene, heptene, octene, nonene, and decene; an alkyne such as acetylene, propyne, butyne, pentyne, hexyne, heptyne, octyne, nonyne, and decyne; and structural isomers and stereoisomers thereof. Examples of the alicyclic hydrocarbon having 3 to 10 carbon atoms include cyclopropane, cyclobutane, cyclopentane, cyclohexane, cycloheptane, cyclooctane, cyclononane, cyclodecane, and structural isomers thereof. Examples of the aromatic hydrocarbon having 6 to 30 carbon atoms include benzene, toluene, xylene, naphthalene, tetrahydronaphthalene, azulene, chrysene, pyrene, benzopyrene, coronene, and the like.

These hydrocarbons may be substituted with one or more substituents. Examples of the substituent include an acetyl group, a hydroxyl group, a carboxyl group, an aldehyde group, a carbonyl group, a cyano group, an amino group, and the like. These hydrocarbons may include at least one hetero atom selected from the group consisting of B, P, S, F, and CI in its structure.

After stopping the supply of the carbon-containing gas when a predetermined time has elapsed, the reaction vessel 10 is cooled to a predetermined temperature, and the boat 12 is removed from the reaction vessel 10. A carbon-containing thin film is thus formed on the surface of the conductive carbon material 1. Note that the thickness of the carbon-containing thin film can be increased by supplying the carbon-containing gas to the reaction vessel 10 for a longer time.

It is preferable that the carbon-containing thin film be homogenously formed on the surface of the conductive carbon material 1 from the viewpoint of ensuring that a homogeneous silicon-containing thin film or silicon-containing alloy thin film is formed by the step (b) (described later). The time in which the carbon-containing gas is supplied to the reaction vessel 10 is preferably adjusted so that the carbon-containing thin film formed on the surface of the conductive carbon material 1 has a thickness of 0.1 to 1000 nm, more preferably 1 to 200 nm, and particularly preferably 10 to 100 nm.

### 1.2.2. Step (b)

The step (b) used in connection with the first embodiment forms the silicon-containing thin film on the conductive carbon material by chemical vapor deposition (CVD) that utilizes the silicon-containing gas after the step (a) has been performed. The step (b) used in connection with the second embodiment forms the silicon-containing alloy thin film on the conductive carbon material by chemical vapor deposition (CVD) that utilizes the silicon-containing gas and the carbon-containing gas after the step (a) has been performed. The step (b) used in connection with the third embodiment forms the silicon-containing alloy thin film on the conductive carbon material by chemical vapor deposition (CVD) that utilizes the silicon-containing gas and the carbon-containing gas in a state in which the step (a) has not been performed. The step (b) can form a homogeneous silicon-containing thin film or silicon-containing alloy thin film on the surface of the conductive carbon material.

The step (b) may be performed as described below, for example.

The conductive carbon material 1 that has been covered with the carbon-containing thin film in the step (a), or the conductive carbon material 1 that has not been subjected to the step (a) is placed on the boat, which is introduced into the reaction vessel 10. Note that the conductive carbon material 1 that has been covered with the carbon-containing thin film may be subjected directly to the step (b) without removing the conductive carbon material 1 subjected to the step (a) from the reaction vessel 10.

The reaction vessel 10 is then set to a vacuum state by driving the vacuum pump 22 to exhaust gas from the reaction vessel 10 through the line L4. The reaction vessel 10 is heated to 450 to 650° C. (preferably 500 to 600° C.) using the furnace 14.

When the temperature inside the reaction vessel 10 has become constant, nitrogen gas is introduced into the reaction vessel 10 from the carrier gas cylinder 16 through the line L1, and the pressure inside the reaction vessel 10 is maintained at a constant pressure of 0.01 to 100 Torr (preferably 0.1 to 50 Torr).

In the methods of producing a silicon alloy/carbon composite according to the second and third embodiments, when the temperature and the pressure inside the reaction vessel 10 have become constant, the carbon-containing gas is supplied from the carbon-containing gas cylinder 18 through the line L2 to introduce a carbon-containing gas/nitrogen mixed gas into the reaction vessel 10. The carbon-containing gas and nitrogen are mixed so that the concentration of the carbon-containing gas in the mixed gas is 0.1 to 5%, and preferably 0.5 to 2.5%. The flow rate of the carbon-containing gas/nitrogen mixed gas is set to about 5 to 500 sccm, and preferably about 10 to 300 sccm. In the example illustrated in FIG. 1, the carbon-containing gas supplied from the carbon-containing gas cylinder 18 is mixed into the flow of the carrier gas. Note that the carrier gas may be bubbled into the carbon-containing gas cylinder 18, and the resulting carbon-containing gas may be introduced into the reaction vessel 10.

Examples of the carbon-containing gas include a hydrocarbon such as a saturated hydrocarbon having 1 to 10 carbon atoms, an unsaturated hydrocarbon having 2 to 10 carbon atoms, an alicyclic hydrocarbon having 3 to 10 carbon atoms, and an aromatic hydrocarbon having 6 to 30 carbon atoms. These hydrocarbons may be used either alone or in combination.

Examples of the saturated hydrocarbon having 1 to 10 carbon atoms include methane, ethane, propane, butane, pentane, hexane, heptane, octane, nonane, decane, and structural isomers thereof. Examples of the unsaturated hydrocarbon having 2 to 10 carbon atoms include an alkene such as ethene, propene, butene, pentene, hexene, heptene, octene, nonene, and decene; an alkyne such as acetylene, propyne, butyne, pentyne, hexyne, heptyne, octyne, nonyne, and decyne; and structural isomers and stereoisomers thereof. Examples of the alicyclic hydrocarbon having 3 to 10 carbon atoms include cyclopropane, cyclobutane, cyclopentane, cyclohexane, cycloheptane, cyclooctane, cyclononane, cyclodecane, and structural isomers thereof. Examples of the aromatic hydrocarbon having 6 to 30 carbon atoms include benzene, toluene, xylene, naphthalene, tetrahydronaphthalene, azulene, chrysene, pyrene, benzopyrene, coronene, and the like.

These hydrocarbons may be substituted with one or more substituents. Examples of the substituent include an acetyl group, a hydroxyl group, a carboxyl group, an aldehyde group, a carbonyl group, a cyano group, an amino group, and the like. These hydrocarbons may include at least one hetero atom selected from the group consisting of B, P, S, F, and CI in its structure.

In the method for producing a silicon/carbon composite according to the first embodiment, after the temperature and the pressure inside the reaction vessel 10 have become constant by introduction of nitrogen gas, the silicon-containing gas is supplied from the silicon-containing gas cylinder 20 through the line L3 to introduce a silicon-containing gas/nitrogen mixed gas into the reaction vessel 10. In the methods for producing a silicon alloy/carbon composite according to the second and third embodiments, simultaneously with the introduction of the carbon-containing gas, the silicon-containing gas is supplied from the silicon-containing gas cylinder 20 through the line L3 to introduce a silicon-containing gas/nitrogen mixed gas into the reaction vessel 10. The silicon-containing gas and nitrogen are mixed so that the concentration of the silicon-containing gas in the mixed gas is 0.01 to 3%, and preferably 0.1 to 2%. The flow rate of the silicon-containing gas/nitrogen mixed gas is set to about 1 to 100 sccm, and preferably about 5 to 50 sccm.

It is preferable to use a silane (polysilane) represented by the following general formula (1) as the silicon-containing gas from the viewpoint of increasing the concentration of silicon in the resulting silicon-containing alloy thin film.

SiₙH₂ₙ₊₂ (1)

wherein n is an integer from 1 to 6.

It is preferable that the silane (polysilane) represented by the general formula (1) be a monosilane, a disilane, or a trisilane.

After stopping the supply of the silicon-containing gas and the carbon-containing gas when a predetermined time has elapsed, the reaction vessel 10 is cooled to a predetermined temperature, and returned to the atmospheric pressure, and the boat 12 is removed from the reaction vessel 10. A silicon-containing thin film or a silicon-containing alloy thin film is thus formed on the surface of the conductive carbon material 1. Note that the thickness of the silicon-containing thin film or the silicon-containing alloy thin film can be increased by supplying either or both of the silicon-containing gas and the carbon-containing gas to the reaction vessel 10 for a longer time. When the silicon/carbon composite or the silicon alloy/carbon composite is used as a negative electrode material for producing an electrical storage device, it is desirable that the silicon-containing thin film or the silicon-containing alloy thin film formed on the surface of the conductive carbon material 1 have a thickness as large as possible from the viewpoint of increasing the capacity of the electrical storage device.

### 2. SILICON/CARBON COMPOSITE AND SILICON ALLOY/CARBON COMPOSITE

According to the first embodiment, a silicon/carbon composite can be produced. Specifically, the silicon/carbon composite according to the first embodiment of the invention includes a conductive carbon material, a carbon-containing thin film being formed on the surface of the conductive carbon material by chemical vapor deposition (CVD) that utilizes a carbon-containing gas, and a silicon-containing thin film that is formed on the conductive carbon material by chemical vapor deposition (CVD) that utilizes a silicon-containing gas. According to the second or third embodiment, a silicon alloy/carbon composite can be produced. Specifically, the silicon alloy/carbon composite according to the second or third embodiment of the invention includes a conductive carbon material, and a silicon-containing alloy thin film that is formed on the conductive carbon material by chemical vapor deposition (CVD) that utilizes a silicon-containing gas and a carbon-containing gas. The above production methods can form a homogeneous silicon-containing thin film or silicon-containing alloy thin film on the surface of the conductive carbon material. By forming a homogeneous silicon-containing thin film or silicon-containing alloy thin film on the surface of the conductive carbon material, it becomes possible to increase the area of contact between the conductive carbon material and the silicon-containing thin film or the silicon-containing alloy thin film, and efficiently cause a conductive additive (described later) to adhere to the silicon-containing thin film or the silicon-containing alloy thin film. A large-capacity electrical storage device can thus be obtained when the silicon/carbon composite or the silicon alloy/carbon composite according to these embodiments of the invention is used as a negative electrode material for producing an electrical storage device. The silicon/carbon composite and the silicon alloy/carbon composite according to these embodiments of the invention are suitable as a negative electrode material for forming an electrical storage device negative electrode.

The volume of silicon or a silicon alloy increases or decreases to a large extent upon insertion or extraction of lithium ions. As a result, silicon or a silicon alloy may be removed from the collector, and the conductive network may break when charge and discharge are repeated, for example. A situation in which silicon or a silicon alloy is removed from the collector can be reduced by forming a homogeneous silicon-containing thin film or silicon-containing alloy thin film on the surface of the conductive carbon material. Therefore, an electrical storage device that exhibits excellent charge-discharge cycle characteristics can be obtained by utilizing the silicon/carbon composite or the silicon alloy/carbon composite according to the embodiments of the invention as a negative electrode material for producing an electrical storage device.

### 3. ELECTRICAL STORAGE DEVICE NEGATIVE ELECTRODE

An electrical storage device negative electrode has a structure in which an active material layer is formed on the surface of a collector. The collector is not particularly limited as long as the collector is formed of a conductive material. For example, a collector formed of a metal such as iron, copper, aluminum, nickel, or stainless steel is used as the collector. It is preferable to use a collector formed of copper. The shape and the thickness of the collector are not particularly limited. It is preferable to use a foil-like collector having a thickness of about 0.0001 to 0.5 mm.

The active material layer includes the above silicon alloy/carbon composite as a negative electrode material (active material), and also includes a conductive additive, a binder, and the like.

Carbon is mainly used as the conductive additive. Examples of the carbon include graphite, activated carbon, acetylene black, furnace black, carbon fibers, fullerenes, and the like. The conductive additive is normally used in an amount of 20 parts by mass or less, and preferably 1 to 15 parts by mass, based on 100 parts by mass of the negative electrode material.

Examples of the binder include a fluorine-containing polymer such as polyvinylidene fluoride (PVDF), polytetrafluoroethylene (PTFE), and a polyvinylidene fluoride-hexafluoropropylene copolymer (PVDF-HFP); a rubber such as styrene-butadiene rubber (SBR), an acrylic-based rubber, polybutadiene, an ethylene-propylene-diene copolymer (EPDM), and sulfonated EPDM; an acrylic-based resin (e.g., a resin that is producing using a (meth)acrylate as the main monomer, and polyacrylic acid); and the like. The binder is normally used in an amount of 30 to 200 parts by mass, and preferably 50 to 150 parts by mass, based on 100 parts by mass of the negative electrode material.

A polymer material such as a cellulose-based polymer (e.g., carboxymethyl cellulose (CMC), diacetyl cellulose, and hydroxypropyl cellulose), polyvinyl alcohol, or a polyalkylene oxide (e.g., polyethylene oxide) may be used as a thickener.

The electrical storage device negative electrode may be produced by kneading the silicon/carbon composite and/or the silicon alloy/carbon composite, the conductive additive, and the binder to prepare a paste, applying the paste to the surface of the collector, and drying the applied paste. The silicon/carbon composite and/or the silicon alloy/carbon composite, the conductive additive, and the binder may be kneaded using a known method. For example, the silicon/carbon composite and/or the silicon alloy/carbon composite, the conductive additive, and the binder may be kneaded using a mixer such as a kneader. The paste may be applied to the surface of the collector using an arbitrary method. For example, the paste may be applied to the surface of the collector using a doctor blade method, a reverse roll method, a direct roll method, a gravure method, or the like.

The thickness of the active material layer is preferably about 0.005 to 5 mm, and more preferably 0.01 to 2 mm. When the thickness of the active material layer is within the above range, an electrolyte solution is efficiently absorbed into the active material layer. As a result, metal ions are easily transferred between the active material included in the active material layer and the electrolyte solution due to charge and discharge, and the resistance of the electrode can be further reduced. Moreover, since the active material layer is not removed from the collector even if the electrode is folded or wound, an electrical storage device negative electrode that exhibits excellent adhesion and excellent flexibility can be obtained.

### 4. EXAMPLES

### 4.1. CNF Pretreatment Step (Step (a))

### (1) Pretreatment of CNF by Acetylene CVD

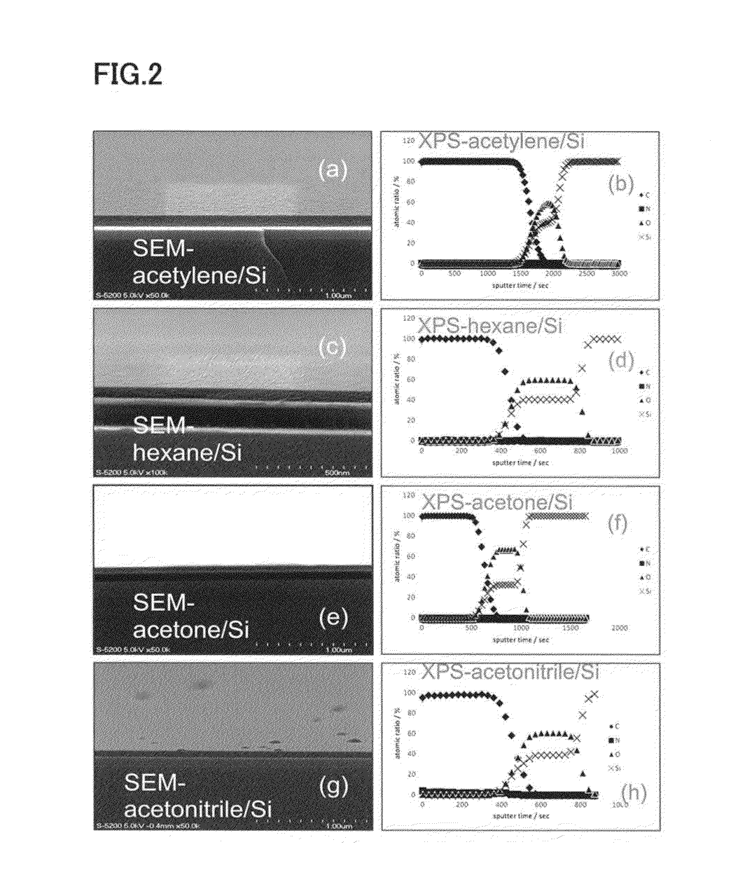

A carbon-containing thin film was formed on the surface of CNF using a CVD device similar to that illustrated in FIG. 1. 25 mg of CNF (“Pyrograf (registered trademark)-III” (product number: PR-25-XT-HHT) manufactured by Sigma-Aldrich) and a small piece of a silicon substrate (SiO₂, thickness: 100 nm) (provided with a thermal oxide film) were placed on a quartz boat, which was introduced into a reaction vessel made of quartz. Nitrogen gas (200 sccm) was introduced into the reaction vessel, and the pressure inside the reaction vessel was adjusted to 600 Torr. The reaction vessel was then heated to 1000° C. When the temperature and the pressure inside the reaction vessel had become constant, an acetylene/nitrogen mixed gas (concentration: 1%) (100 sccm) was introduced into the reaction vessel. The supply of the acetylene gas was stopped when a predetermined time had elapsed, and the reaction vessel was allowed to cool to room temperature. The reaction vessel was then returned to the atmospheric pressure, and the resulting CNF sample was collected. FIG. 2(a) illustrates an SEM photograph of the sample formed on the silicon substrate (provided with a thermal oxide film). FIG. 2(b) illustrates the XPS depth profile of the sample formed on the silicon substrate (SiO₂, thickness: 100 nm) (provided with a thermal oxide film), and Table 1 illustrates the numerical data. The deposition rate of the carbon-containing thin film was estimated to be about 3.5 nm/min based on the SEM photograph illustrated in FIG. 2(a), and it was confirmed from FIG. 2(b) and Table 1 that the composition in the XPS depth direction was uniform.

### (2) Pretreatment of CNF by Hexane CVD

A carbon-containing thin film was formed on the surface of CNF using a CVD device similar to that illustrated in FIG. 1. 25 mg of CNF (“Pyrograf (registered trademark)-III” (product number: PR-25-XT-HHT) manufactured by Sigma-Aldrich) and a small piece of a silicon substrate (SiO₂, thickness: 100 nm) (provided with a thermal oxide film) were placed on a quartz boat, which was introduced into a reaction vessel made of quartz. Nitrogen gas (200 sccm) was introduced into the reaction vessel, and the pressure inside the reaction vessel was adjusted to 100 Torr. The reaction vessel was then heated to 800° C. When the temperature and the pressure inside the reaction vessel had become constant, a hexane/nitrogen mixed gas was introduced into the reaction vessel. The amount of hexane supplied was controlled by controlling the temperature of the canister and the pressure inside the supply line. The hexane concentration in the hexane/nitrogen mixed gas introduced into the reaction vessel was about 2%. The supply of hexane was stopped when a predetermined time had elapsed, and the reaction vessel was allowed to cool to room temperature. The reaction vessel was then returned to the atmospheric pressure, and the resulting CNF sample was collected. FIG. 2(c) illustrates an SEM photograph of the sample formed on the silicon substrate (provided with a thermal oxide film). FIG. 2(d) illustrates the XPS depth profile of the sample formed on the silicon substrate (provided with a thermal oxide film), and Table 1 illustrates the numerical data. The deposition rate of the carbon-containing thin film was estimated to be about 7 nm/min based on the SEM photograph illustrated in FIG. 2(c), and it was confirmed from FIG. 2(d) and Table 1 that the composition in the XPS depth direction was uniform.

### (3) Pretreatment of CNF by Acetone CVD

A carbon-containing thin film was formed on the surface of CNF using a CVD device similar to that illustrated in FIG. 1. 25 mg of CNF (“Pyrograf (registered trademark)-III” (product number: PR-25-XT-HHT) manufactured by Sigma-Aldrich) and a small piece of a silicon substrate (SiO₂, thickness: 100 nm) (provided with a thermal oxide film) were placed on a quartz boat, which was introduced into a reaction vessel made of quartz. Nitrogen gas (200 sccm) was introduced into the reaction vessel, and the pressure inside the reaction vessel was adjusted to 100 Torr. The reaction vessel was then heated to 950° C. When the temperature and the pressure inside the reaction vessel had become constant, nitrogen gas (20 sccm) was bubbled into a container holding acetone, and acetone was mixed with nitrogen gas (80 sccm) that was supplied separately to introduce an acetone/nitrogen mixed gas into the reaction vessel. The amount of acetone supplied was controlled by controlling the temperature of the canister and the pressure inside the supply line. The acetone concentration in the acetone/nitrogen mixed gas introduced into the reaction vessel was about 3.5%. The supply of acetone was stopped when a predetermined time had elapsed, and the reaction vessel was allowed to cool to room temperature. The reaction vessel was then returned to the atmospheric pressure, and the resulting CNF sample was collected. FIG. 2(e) illustrates an SEM photograph of the sample formed on the silicon substrate (provided with a thermal oxide film). FIG. 2(f) illustrates the XPS depth profile of the sample formed on the silicon substrate (provided with a thermal oxide film), and Table 1 illustrates the numerical data. The deposition rate of the carbon-containing thin film was estimated to be about 1.5 nm/min based on the SEM photograph illustrated in FIG. 2(e), and it was confirmed from FIG. 2(f) and Table 1 that the composition in the XPS depth direction was uniform.

### (4) Pretreatment of CNF by Acetonitrile CVD

A carbon-containing thin film was formed on the surface of CNF using a CVD device similar to that illustrated in FIG. 1. 25 mg of CNF (“Pyrograf (registered trademark)-III” (product number: PR-25-XT-HHT) manufactured by Sigma-Aldrich) and a small piece of a silicon substrate (SiO₂, thickness: 100 nm) (provided with a thermal oxide film) were placed on a quartz boat, which was introduced into a reaction vessel made of quartz. Nitrogen gas (200 sccm) was introduced into the reaction vessel, and the pressure inside the reaction vessel was adjusted to 400 Torr. The reaction vessel was then heated to 1000° C. When the temperature and the pressure inside the reaction vessel had become constant, nitrogen gas (20 sccm) was bubbled into a container holding acetonitrile, and acetonitrile was mixed with nitrogen gas (80 sccm) that was supplied separately to introduce an acetonitrile/nitrogen mixed gas into the reaction vessel. The amount of acetonitrile supplied was controlled by controlling the temperature of the canister and the pressure inside the supply line. The acetonitrile concentration in the acetonitrile/nitrogen mixed gas introduced into the reaction vessel was about 1.5%. The supply of acetonitrile was stopped when a predetermined time had elapsed, and the reaction vessel was allowed to cool to room temperature. The reaction vessel was then returned to the atmospheric pressure, and the resulting CNF sample was collected. FIG. 2(g) illustrates an SEM photograph of the sample formed on the silicon substrate (provided with a thermal oxide film). FIG. 2(h) illustrates the XPS depth profile of the sample formed on the silicon substrate (provided with a thermal oxide film), and Table 1 illustrates the numerical data. The deposition rate of the carbon-containing thin film was estimated to be about 2.5 nm/min based on the SEM photograph illustrated in FIG. 2(g), and it was confirmed from FIG. 2(h) and Table 1 that the composition in the XPS depth direction was uniform, and about 2 atom % of nitrogen was introduced into the carbon-containing thin film.

TABLE 1

| | | | Deposition rate of | | | |
|---|---|---|---|---|---|---|
| | | | carbon-containing | | | |
| Carbon | Temp. | Pressure | thin film | C | N | O |
| source | (° C.) | (Torr) | (nm/min) | (%) | (%) | (%) |
| Acetylene | 1000 | 600 | 3.5 | 100 | 0 | 0 |
| Hexane | 800 | 100 | 7 | 100 | 0 | 0 |
| Acetone | 950 | 100 | 1.5 | 100 | 0 | 0 |
| Acetonitrile | 1000 | 400 | 2.5 | 98.5 | 1.5 | 0 |

### 4.2. Production and Evaluation of Silicon/Carbon Composite

4.2.1. Coating of Pretreated CNF with Silicon (Step (b))

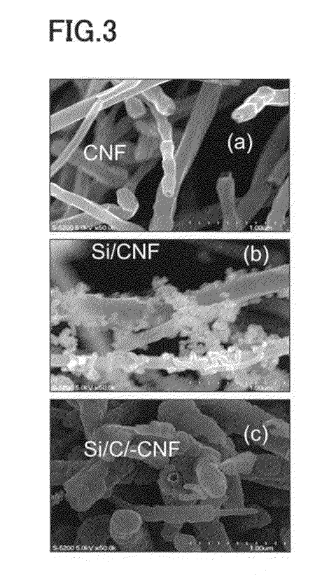

A silicon-containing thin film was formed on the surface of the CNF pretreated by acetylene CVD (see (1)) using a CVD device similar to that illustrated in FIG. 1. The CNF pretreated by acetylene CVD was placed on a quartz boat, which was introduced into a reaction vessel made of quartz. Note that the CNF pretreated by acetylene CVD (see (1)) may be directly coated with silicon without collecting the CNF. The reaction vessel was set to a vacuum state by exhausting gas, and heated to 550° C. When the temperature inside the reaction vessel had become constant, nitrogen gas (380 sccm) was introduced into the reaction vessel, and the pressure inside the reaction vessel was adjusted to 10 Torr. An Ar-diluted silane gas (10%) (20 sccm) was mixed with the nitrogen gas to introduce a silane/nitrogen mixed gas into the reaction vessel. The silane concentration in the silane/nitrogen mixed gas introduced into the reaction vessel was about 0.5%. The supply of silane was stopped when a predetermined time had elapsed, and the reaction vessel was allowed to cool to room temperature. The reaction vessel was then returned to the atmospheric pressure, and the resulting CNF sample was collected. FIG. 3(c) illustrates an SEM photograph of the resulting sample. FIG. 3(a) illustrates an SEM photograph of the uncoated CNF (reference), and FIG. 3(b) illustrates an SEM photograph of the CNF that was coated with silicon in a state in which the CNF was not pretreated by acetylene CVD (see (1)) (reference). It was confirmed from the SEM photograph illustrated in FIG. 3(c) that a silicon-containing thin film was homogeneously formed on the surface of the CNF, and the deposition rate of the silicon-containing thin film was estimated to be about 1.5 nm/min. In the SEM photograph illustrated in FIG. 3(b), particulate silicon adheres to the surface of the CNF.

When the CNF that was pretreated by hexane CVD, acetone CVD, or acetonitrile CVD (see (2) to (4)) was coated with silicon, results similar to those obtained for the CNF that was pretreated by acetylene CVD were obtained.

### 4.2.2. Production of Cell and Charge-Discharge Performance Test

A half-cell (CR-2032) was produced using the silicon/CNF composite produced as described above. 40 mg of the silicon/CNF composite, 2.5 mg of carbon black, and 180 mg of a binder aqueous solution (styrene-butadiene latex, solid content: 15 wt %) were mixed using a mortar to prepare a paste. The paste was applied to a copper foil, and dried at 60° C. for 1 hour. A disc having a diameter of 14 mm was cut from the copper foil to obtain a negative electrode. A coin cell was assembled in a glovebox filled with argon gas. A lithium foil was used as a positive electrode, and 1 M LiPF₆/ethylene carbonate-diethyl carbonate (volume ratio: 1:2) was used as an electrolyte.

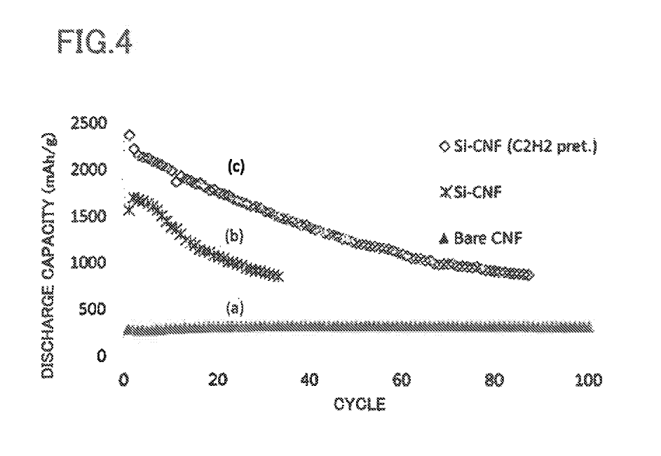

The charge-discharge cycle characteristics were evaluated at a rate of C/10 (i.e., 10 hours is required to complete charge or discharge) and a voltage of 0.02 to 1.5 V using an MSTAT4 potentiostat/galvanostat (manufactured by Arbin). FIG. 4 is a graph illustrating the charge-discharge cycle characteristics of the untreated CNF, the CNF that was coated with silicon without being subjected to the pretreatment, and the CNF that was coated with silicon after being subjected to the pretreatment. Table 2 illustrates the initial discharge capacity and the discharge capacity retention ratio (tenth cycle) of each CNF. As illustrated in Table 2, the CNF that was coated with silicon after being subjected to the carbon coating treatment showed an initial discharge capacity (first cycle) of about 2200 mAh/g, and showed a discharge capacity of about 1000 mAh/g after the 80th cycle (i.e., exhibited a high discharge capacity retention ratio). These values were higher than those of the CNF that was coated with silicon without being subjected to the pretreatment (1700 mAh/g or less in the first cycle, and 1000 mAh/g or less in the 20th cycle) and the untreated CNF (278 mAh/g or less).

TABLE 2

| | Initial discharge | Discharge capacity |
|---|---|---|
| Negative electrode | capacity | retention ratio after |
| material | (mAh/g) | 10th cycle (%) |
| Bare CNF | 328 | 99 |
| Si/CNF (firth batch) | 1698 | 81 |
| Si/CNF (second batch) | 1956 | 70 |
| Si/CNF (third batch) | 1478 | 83 |
| Si/C/CNF (firth batch) | 2371 | 84 |
| Si/C/CNF (second | 2427 | 87 |
| batch) | | |
| Si/C/CNF (third batch) | 2140 | 94 |

### 4.2.3. Production and Cell Characteristics of Silicon/Graphite Composite

A carbon-containing thin film was formed on the surface of a graphite powder using a CVD device similar to that illustrated in FIG. 1. 25 mg of a graphite powder (“Graphite Powder” manufactured by Wako Pure Chemical Industries, Ltd.) and a small piece of a silicon substrate (provided with a thermal oxide film) were placed on a quartz boat, which was introduced into a reaction vessel made of quartz. Nitrogen gas (200 sccm) was introduced into the reaction vessel, and the pressure inside the reaction vessel was adjusted to 600 Torr. The reaction vessel was then heated to 1000° C. When the temperature and the pressure inside the reaction vessel had become constant, an acetylene/nitrogen mixed gas (concentration: 1%) (100 sccm) was introduced into the reaction vessel. The supply of the acetylene gas was stopped when a predetermined time had elapsed, and the reaction vessel was allowed to cool to room temperature. The reaction vessel was then returned to the atmospheric pressure, and the resulting graphite sample was collected.

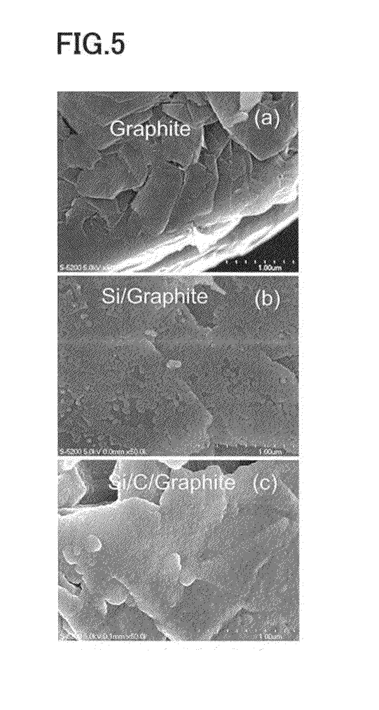

A silicon-containing thin film was formed on the surface of the graphite pretreated by acetylene CVD (see above) using a CVD device similar to that illustrated in FIG. 1. The graphite pretreated by acetylene CVD was placed on a quartz boat, which was introduced into a reaction vessel made of quartz. The reaction vessel was set to a vacuum state by exhausting gas, and heated to 550° C. When the temperature inside the reaction vessel had become constant, nitrogen gas (380 sccm) was introduced into the reaction vessel, and the pressure inside the reaction vessel was adjusted to 10 Torr. An Ar-diluted silane gas (10%) (20 sccm) was mixed with the nitrogen gas to introduce a silane/nitrogen mixed gas into the reaction vessel. The silane concentration in the silane/nitrogen mixed gas introduced into the reaction vessel was about 0.5%. The supply of silane was stopped when a predetermined time had elapsed, and the reaction vessel was allowed to cool to room temperature. The reaction vessel was then returned to the atmospheric pressure, and the resulting graphite sample was collected. FIG. 5(c) illustrates an SEM photograph of the resulting sample. FIG. 5(a) illustrates an SEM photograph of the uncoated graphite (reference), and FIG. 5(b) illustrates an SEM photograph of the graphite that was coated with silicon in a state in which the graphite was not pretreated as described above (reference). As illustrated in FIG. 5(b) (SEM photograph), silicon is deposited on the graphite (that was not pretreated) so that microparticles are fused, and the graphite is observed. As illustrated in FIG. 5(c) (SEM photograph), silicon is homogenously deposited on the graphite (that was pretreated by acetylene CVD), and the graphite layer was not observed.

A half-cell (CR-2032) was produced using the silicon/graphite composite sample produced as described above. 40 mg of the silicon/graphite composite, 2.5 mg of carbon black, and 180 mg of a binder aqueous solution (styrene-butadiene latex, solid content: 15 wt %) were mixed using a mortar to prepare a paste. The paste was applied to a copper foil, and dried at 60° C. for 1 hour. A disc having a diameter of 14 mm was cut from the copper foil to obtain a negative electrode. A coin cell was assembled in a glovebox filled with argon gas. A lithium foil was used as a positive electrode, and 1 M LiPF₆/ethylene carbonate-diethyl carbonate (volume ratio: 1:2) was used as an electrolyte.

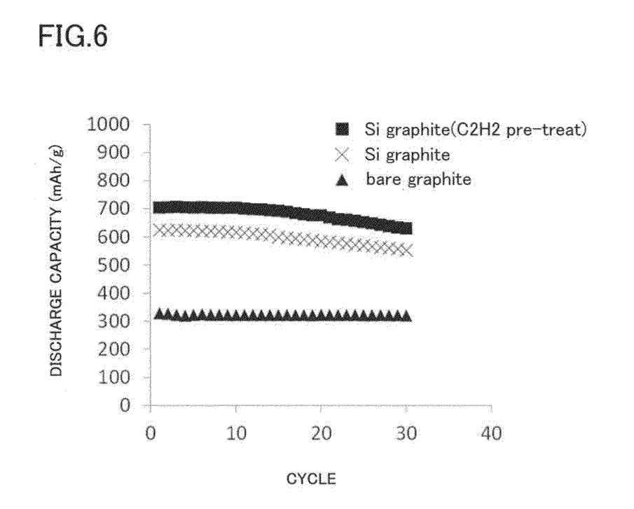

The charge-discharge cycle characteristics were evaluated at a rate of C/10 (i.e., 10 hours is required to complete charge or discharge) and a voltage of 0.02 to 1.5 V using an MSTAT4 potentiostat/galvanostat (manufactured by Arbin). FIG. 6 is a graph illustrating the charge-discharge cycle characteristics of the untreated graphite, the graphite that was coated with silicon without being subjected to the pretreatment, and the graphite that was coated with silicon after being subjected to the pretreatment. Table 3 illustrates the initial discharge capacity and the discharge capacity retention ratio (30th cycle) of each graphite. As illustrated in Table 3, the graphite that was coated with silicon after being subjected to the carbon coating treatment showed a maximum discharge capacity of about 706 mAh/g, and had a discharge capacity retention ratio of 89% after the 30th cycle. These values were higher than those of the graphite that was coated with silicon without being subjected to the pretreatment (maximum discharge capacity: about 627 mAh/g, discharge capacity retention ratio: 88% (after the 30th cycle)) and the untreated graphite (330 mAh/g or less).

TABLE 3

| | Maximum discharge | Discharge capacity |
|---|---|---|
| Negative electrode | capacity | retention ratio after |
| material | (mAh/g) | 30th cycle (%) |
| Bare graphite | 330 | 97 |
| Si-graphite (C₂H₂ | 706 | 89 |
| pretreatment) | | |
| Si-graphite | 627 | 88 |

### 4.3. Production and Evaluation of Silicon Alloy/Carbon Composite

4.3.1. Coating of Pretreated CNF with Silicon Alloy (Step (b))

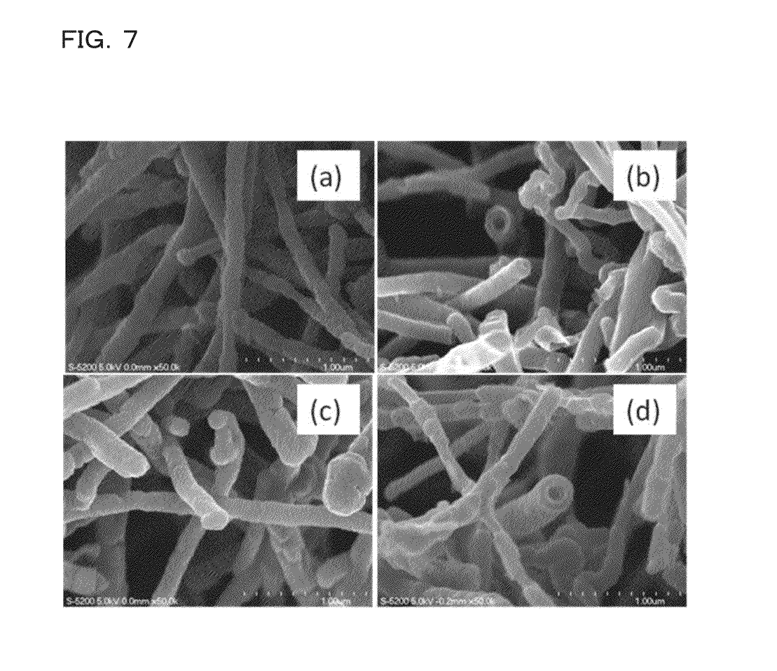

A silicon-containing alloy thin film was formed on the surface of the CNF pretreated by acetylene CVD (see (1)) using a CVD device similar to that illustrated in FIG. 1. The CNF pretreated by acetylene CVD was placed on a quartz boat, which was introduced into a reaction vessel made of quartz. Note that the CNF pretreated by acetylene CVD (see (1)) may be directly coated with a silicon alloy without collecting the CNF. The reaction vessel was set to a vacuum state by exhausting gas, and heated to 550° C. When the temperature inside the reaction vessel had become constant, nitrogen gas (380 sccm) was introduced into the reaction vessel, and the pressure inside the reaction vessel was adjusted to 10 Torr. An Ar-diluted silane gas (10%) (20 sccm) was mixed with the nitrogen gas to introduce a silane/carbon-containing gas/nitrogen mixed gas into the reaction vessel. The silane concentration in the silane/carbon-containing gas/nitrogen mixed gas introduced into the reaction vessel was about 1%, and the carbon-containing gas concentration in the silane/carbon-containing gas/nitrogen mixed gas introduced into the reaction vessel was 0.75 to 2%. The supply of silane and the carbon-containing gas was stopped when a predetermined time had elapsed, and the reaction vessel was allowed to cool to room temperature. The reaction vessel was then returned to the atmospheric pressure, and the resulting CNF sample was collected. FIG. 7 illustrates an SEM photograph of the resulting sample. FIG. 7(a) illustrates an SEM photograph of the CNF sample when hexane was used as the carbon-containing gas, FIG. 7(b) illustrates an SEM photograph of the CNF sample when acetone was used as the carbon-containing gas, FIG. 7(c) illustrates an SEM photograph of the CNF sample when acetonitrile was used as the carbon-containing gas, and FIG. 7(d) illustrates an SEM photograph of the CNF sample when methanol was used as the carbon-containing gas. It was confirmed from the SEM photographs illustrated in FIG. 7 that a silicon-containing alloy thin film was homogenously formed on the surface of the CNF when each carbon-containing gas was used. Table 4 illustrates the deposition conditions, the deposition rate of the silicon-containing alloy thin film, and the composition of the silicon-containing alloy thin film when each carbon-containing gas was used.

TABLE 4

| Carbon source | Hexane | Acetone | Acetonitrile | Methanol |
|---|---|---|---|---|
| Reaction | 800 | 800 | 550 | 600 |
| temperature (° C.) | | | | |
| Reactor pressure | 100 | 100 | 100 | 100 |
| (Torr) | | | | |
| Total flow rate | 200 | 200 | 200 | 200 |
| (sccm) | | | | |
| Silane | 2 | 2 | 2 | 2 |
| concentration (%) | | | | |
| Carbon source | 20 | 20 | 20 | 20 |
| bubbling flow rate | | | | |
| (sccm) | | | | |
| Carbon source | 2 | 1.75 | 0.75 | 0.75 |
| concentration (%) | | | | |
| Carbon source | 40 | 70 | 30 | 30 |
| vapor pressure | | | | |
| (0° C.) (Torr) | | | | |
| Deposition rate | 10 | 10 | 5 | — |
| (nm/min) | | | | |
| Composition | Si_{0.35}C_{0.65} | Si_{0.34}C_{0.33}O_{0.33} | Si_{0.80}C_{0.15}N_{0.05} | Si_{0.54}C_{0.12}O_{0.34} |
| (XPS) | | | | |

When the CNF that was pretreated by hexane CVD, acetone CVD, or acetonitrile CVD (see (2) to (4)) was coated with a silicon alloy, results similar to those obtained for the CNF that was pretreated by acetylene CVD were obtained.

### 4.3.2. Production of Cell and Charge-Discharge Performance Test

A half-cell (CR-2032) was produced using the silicon alloy/CNF composite produced as described above. 40 mg of the silicon alloy/CNF composite, 2.5 mg of carbon black, and 180 mg of a binder aqueous solution (styrene-butadiene latex, solid content: 15 wt %) were mixed using a mortar to prepare a paste. The paste was applied to a copper foil, and dried at 60° C. for 1 hour. A disc having a diameter of 14 mm was cut from the copper foil to obtain a negative electrode. A coin cell was assembled in a glovebox filled with argon gas. A lithium foil was used as a positive electrode, and 1 M LiPF₆/ethylene carbonate-diethyl carbonate (volume ratio: 1:2) was used as an electrolyte.

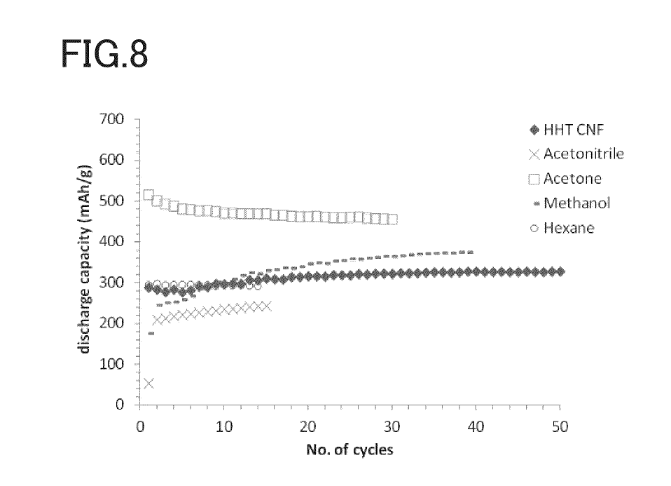

The charge-discharge cycle characteristics were evaluated at a rate of C/10 (i.e., 10 hours is required to complete charge or discharge) and a voltage of 0.02 to 1.5 V using an MSTAT4 potentiostat/galvanostat (manufactured by Arbin). FIG. 8 is a graph illustrating the charge-discharge cycle characteristics of the untreated CNF (HHT CNF) and the CNF that was coated with a silicon alloy after being subjected to the pretreatment. Table 5 illustrates the maximum capacity and the capacity retention ratio (tenth cycle) of each CNF. As is clear from the results illustrated in FIG. 8 and Table 5, the CNF that was coated with a silicon alloy showed a high capacity retention ratio after the tenth cycle (i.e., exhibited excellent charge-discharge cycle characteristics).

TABLE 5

| | Silicon | | Capacity | Estimated |
|---|---|---|---|---|
| | concen- | Maximum | retention ratio | capacity*¹ |
| Sample | tration | capacity | (%) after tenth | (mAh/g |
| (composition) | (wt %) | (mAh/g) | cycle | alloy) |
| Hexane | 29 | 296.7 | 99.1 | 223 |
| (Si_{0.35}C_{0.65}) | | | | |
| Acetone | 36 | 514.6 | 91.3 | 853 |
| (Si_{0.34}C_{0.33}O_{0.33}) | | | | |
| Acetonitrile | 54 | 234.7*² | — | 216*² |
| (Si_{0.80}C_{0.15}N_{0.05}) | | | | |
| Methanol | 21 | 375.1*³ | — | 552*³ |
| (Si_{0.54}C_{0.12}O_{0.34}) | | | | |

*¹Estimated from a change in weight after silicon alloy CVD.
*²Estimated from the value after the tenth cycle.
*³Estimated from the value after the 30th cycle.

It is considered that adhesion between a silicon alloy and CNF is high when the surface of CNF is homogeneous. In such a case, it is considered that the step (b) that forms the silicon-containing alloy thin film directly on the conductive carbon material by CVD that utilizes the silicon-containing gas and the carbon-containing gas can be performed without performing the step (a) that forms the carbon-containing thin film.

While the invention has been described in conjunction with specific embodiments thereof, it is evident that many alternatives, modifications, and variations will be apparent to those skilled in the art in light of the foregoing description. Accordingly, it is intended to embrace all such alternatives, modifications, and variations as fall within the spirit and broad scope of the appended claims. The present invention may suitably comprise, consist or consist essentially of the elements disclosed and may be practiced in the absence of an element not disclosed. Furthermore, if there is language referring to order, such as first and second, it should be understood in an exemplary sense and not in a limiting sense. For example, it can be recognized by those skilled in the art that certain steps can be combined into a single step.

The singular forms “a”, an and the include plural referents, unless the context clearly dictates otherwise.

“Comprising” in a claim is an open transitional term which means the subsequently identified claim elements are a nonexclusive listing i.e. anything else may be additionally included and remain within the scope of “comprising.” “Comprising” is defined herein as necessarily encompassing the more limited transitional terms “consisting essentially of” and “consisting of”; “comprising” may therefore be replaced by “consisting essentially of” or “consisting of” and remain within the expressly defined scope of “comprising”.

“Providing” in a claim is defined to mean furnishing, supplying, making available, or preparing something. The step may be performed by any actor in the absence of express language in the claim to the contrary.

Optional or optionally means that the subsequently described event or circumstances may or may not occur. The description includes instances where the event or circumstance occurs and instances where it does not occur.

Ranges may be expressed herein as from about one particular value, and/or to about another particular value. When such a range is expressed, it is to be understood that another embodiment is from the one particular value and/or to the other particular value, along with all combinations within said range.

All references identified herein are each hereby incorporated by reference into this application in their entireties, as well as for the specific information for which each is cited.

### REFERENCE SIGNS LIST

1: conductive carbon material, 10: reaction vessel, 12: boat, 14: furnace, 16: carrier gas cylinder, 18: carbon-containing gas cylinder, 20: silicon-containing gas cylinder, 22: vacuum pump, 100: CVD thin film-forming device

What is claimed is:

1. A method for producing a silicon/carbon composite comprising:
forming a carbon-containing thin film on a surface of a conductive carbon material by chemical vapor deposition (CVD) that utilizes a carbon-containing gas; and
forming a silicon-containing thin film on the conductive carbon material by chemical vapor deposition (CVD) that utilizes a silicon-containing gas.

2. The method for producing a silicon/carbon composite of claim 1, wherein the conductive carbon material is carbon nanofibers or a graphite powder.

3. The method for producing a silicon/carbon composite of claim 1, wherein the carbon-containing gas is at least one gas selected from the group consisting of a saturated hydrocarbon having 1 to 10 carbon atoms that is unsubstituted or substituted with a substituent, an unsaturated hydrocarbon having 2 to 10 carbon atoms that is unsubstituted or substituted with a substituent, an alicyclic hydrocarbon having 3 to 10 carbon atoms that is unsubstituted or substituted with a substituent, and an aromatic hydrocarbon having 6 to 30 carbon atoms that is unsubstituted or substituted with a substituent.

4. The method for producing a silicon/carbon composite of claim 3, wherein the substituent is at least one substituent selected from the group consisting of an acetyl group, a hydroxyl group, a carboxyl group, an aldehyde group, a carbonyl group, a cyano group, an amino group, B, P, S, F, and Cl.

5. The method for producing a silicon/carbon composite of claim 1, wherein the silicon-containing gas is a gas represented by formula (1),
SiₙH₂ₙ₊₂ (1)
wherein n is an integer from 1 to 6.

6. A method for producing a silicon alloy/carbon composite comprising:
forming a carbon-containing thin film on a surface of a conductive carbon material by chemical vapor deposition (CVD) that utilizes a carbon-containing gas; and
forming a silicon-containing alloy thin film on the conductive carbon material by chemical vapor deposition (CVD) that utilizes a silicon-containing gas and a carbon-containing gas.

7. The method for producing a silicon alloy/carbon composite of claim 6, wherein the carbon-containing gas is at least one gas selected from the group consisting of a saturated hydrocarbon having 1 to 10 carbon atoms that is unsubstituted or substituted with a substituent, an unsaturated hydrocarbon having 2 to 10 carbon atoms that is unsubstituted or substituted with a substituent, an alicyclic hydrocarbon having 3 to 10 carbon atoms that is unsubstituted or substituted with a substituent, and an aromatic hydrocarbon having 6 to 30 carbon atoms that is unsubstituted or substituted with a substituent.

8. The method for producing a silicon alloy/carbon composite of claim 7, wherein the substituent is at least one substituent selected from the group consisting of an acetyl group, a hydroxyl group, a carboxyl group, an aldehyde group, a carbonyl group, a cyano group, an amino group, B, P, S, F, and Cl.

9. The method for producing a silicon alloy/carbon composite of claim 6, wherein the silicon-containing gas is a gas represented by the following general formula (1),
SiₙH₂ₙ₊₂ (1)
wherein n is an integer from 1 to 6.

10. The method for producing a silicon alloy/carbon composite of claim 6, wherein the conductive carbon material is carbon nanofibers or a graphite powder.

11. A method for producing a silicon alloy/carbon composite comprising:
forming a silicon-containing alloy thin film on a surface of a conductive carbon material by chemical vapor deposition (CVD) that utilizes a silicon-containing gas and a carbon-containing gas.

12. A silicon/carbon composite comprising:
a conductive carbon material, a carbon-containing thin film being formed on the surface of the conductive carbon material by chemical vapor deposition (CVD) that utilizes a carbon-containing gas; and
a silicon-containing thin film that is formed on the conductive carbon material by chemical vapor deposition (CVD) that utilizes a silicon-containing gas.

13. The silicon/carbon composite of claim 12, wherein the carbon-containing thin film formed on the surface of the conductive carbon material has a thickness of 0.1 to 1000 nm.

14. The silicon/carbon composite of claim 12, the silicon/carbon composite being used as a negative electrode material for forming an electrical storage device negative electrode.

15. A silicon alloy/carbon composite comprising:
a conductive carbon material; and
a silicon-containing alloy thin film that is formed on the conductive carbon material by chemical vapor deposition (CVD) that utilizes a silicon-containing gas and a carbon-containing gas.

16. The silicon alloy/carbon composite of claim 15, wherein a carbon-containing thin film formed on the surface of the conductive carbon material by chemical vapor deposition (CVD) that utilizes a carbon-containing gas has a thickness of 0.1 to 1000 nm.

17. The silicon alloy/carbon composite of claim 15, the silicon alloy/carbon composite being used as a negative electrode material for forming an electrical storage device negative electrode.
